(19) United States
(12) Patent Application Publication
(10) Pub. No.: US 2011/0215439 A1
(43) Pub. Date: Sep. 8, 2011

(54) EPITAXIAL GROWTH SUBSTRATE, MANUFACTURING METHOD THEREOF, NITRIDE-BASED COMPOUND SEMICONDUCTOR SUBSTRATE, AND NITRIDE-BASED COMPOUND SEMICONDUCTOR SELF-SUPPORTING SUBSTRATE

(76) Inventor: Satoru MORIOKA, Toda-shi (JP)

(21) Appl. No.: 13/042,129

(22) Filed: Mar. 7, 2011

(30) Foreign Application Priority Data
Mar. 8, 2010 (JP) 2010-050013

(51) Int. Cl. H01L 29/20; B32B 3/00; H01L 21/02

(52) U.S. Cl. 257/615; 428/141; 438/795; 257/E29.089; 257/E21.328

(57) ABSTRACT

An epitaxial growth substrate includes: a surface not roughening over a surface roughness of 10 nm during a temperature-rise process by which a temperature increases until reaching a growth temperature of a nitride-based compound semiconductor layer, the growth temperature being 900° C. to 1050° C., wherein the nitride-based compound semiconductor layer is epitaxially grown directly on the epitaxial growth substrate at the growth temperature.

### BACKGROUND OF THE INVENTION

1. Field of the Invention

The present invention relates to an epitaxial growth substrate, a manufacturing method thereof, a nitride-based compound semiconductor substrate, and a nitride-based compound semiconductor self-supporting substrate, and, in particular, relates to a technology which is useful to grow a nitride-based semiconductor thick film layer directly on an epitaxial growth substrate.

2. Description of the Related Art

Conventionally, there is known a semiconductor device (for example, an electronic device or an optical device) manufactured by epitaxial growth of a nitride-based compound semiconductor (GaN-based semiconductor, hereinafter) such as gallium nitride (GaN) on a substrate (epitaxial growth substrate). In the semiconductor device, a substrate composed of sapphire or silicon carbide (SiC) is mainly used. However, a lattice mismatch is large between such substrate material and the GaN-based semiconductor. Consequently, the epitaxial growth of the GaN-based semiconductor on the substrate causes a lattice defect of a strain. The lattice defect caused in the GaN-based semiconductor (epitaxial layer) becomes a factor to decrease properties of the semiconductor device. In order to solve the problem resulted from the lattice mismatch, various growth methods thereof are developed.

For example, Japanese Patent Application Laid-open Publication No. 2003-257854 discloses using an NdGaO₃ substrate (NGO substrate, hereinafter) having a lattice constant similar to a lattice constant of a GaN-based semiconductor so that the NGO substrate and the GaN-based semiconductor are pseudomorphic. More specifically, a technology is disclosed therein, the technology by which a GaN thick film layer is grown on an NGO substrate by hydride vapor phase epitaxy (HVPE) so that a GaN self-supporting substrate (a substrate consisting of only GaN) is manufactured. On the NGO (011) surface, the length of the a axis of NGO and the lattice constant of GaN in the [11-20] direction nearly match. Therefore, the above-described problem resulted from the lattice mismatch can be solved. Accordingly, the use of the GaN self-supporting substrate as a substrate for a semiconductor device can improve the properties of the semiconductor device.

In general, a GaN thick film layer is grown at a growth temperature of around 1000° C. However, the quality of an NGO substrate is changed when the NGO substrate is exposed to a source gas under such a high temperature of around 1000° C., and accordingly, the quality of the crystal of the GaN thick film layer declines. Then, there is proposed a technology by which a GaN thin film layer referred to as a low-temperature protection layer is grown on an NGO substrate at around 600° C. before growing a GaN thick film layer, whereby the NGO substrate is protected, according to Japanese Patent Application Laid-open Publication No. 2003-257854 and Japanese Patent Application Laid-open Publication No. 2000-4045, for example.

Recently, it is found by an experiment conducted by inventors including the present inventor that a GaN monocrystal can be obtained with excellent duplicability when the surface roughness of an NGO substrate before growing a GaN thick film layer thereon is 0.2 nm to 10 nm. More specifically, when a GaN thick film layer is grown on an NGO substrate at around 1000° C., the GaN thick film layer composed of a high-quality monocrystal can be obtained by adjusting a temperature-rise process in such a way that the surface roughness of the NGO substrate before growing the GaN thick film layer is within the range from 0.2 nm to 10 nm. It does not require growing a low-temperature protection layer. That is, a GaN thick film layer composed of a high-quality monocrystal can be obtained even by directly growing the GaN thick film layer on an NGO substrate.

### SUMMARY OF THE INVENTION

However, the behavior of the surface of an NGO substrate at around 1000° C. is unstable, and hence it often happens that the surface roughness of the NGO substrate exceeds 10 nm even by performing the temperature-rise process described above. In such cases, a high-quality GaN monocrystal is not obtained under the condition of growing a GaN thick film layer at around 1000° C. Instead, a GaN polycrystal is obtained. Thus, manufacturing a GaN-based semiconductor substrate by the above-described method has a problem in the productivity thereof.

In view of the circumstances, a main object of the present invention is to provide a technology by which a GaN-based semiconductor substrate is manufactured with excellent productivity when the GaN-based semiconductor substrate is manufactured by growing a GaN-based thick layer directly on an epitaxial growth substrate composed of NdGaO₃ (NGO) or the like .

To achieve the object mentioned above, according to a first aspect of the present invention, there is provided an epitaxial growth substrate including: a surface not roughening over a surface roughness of 10 nm during a temperature-rise process by which a temperature increases until reaching a growth temperature of a nitride-based compound semiconductor layer, the growth temperature being 900° C. to 1050° C., wherein the nitride-based compound semiconductor layer is epitaxially grown directly on the epitaxial growth substrate at the growth temperature.

According to a second aspect of the present invention, there is provided a nitride-based compound semiconductor substrate including: the epitaxial growth substrate; and a nitride-based compound semiconductor layer disposed on the epitaxial growth substrate, wherein the nitride-based compound semiconductor layer is epitaxially grown directly on the epitaxial growth substrate.

According to a third aspect of the present invention, there is provided a nitride-based compound semiconductor self-supporting substrate obtained by detaching the nitride-based compound semiconductor layer from the nitride-based compound semiconductor substrate, slicing the detached nitride-based compound semiconductor layer, and polishing the sliced nitride-based compound semiconductor layer.

According to a fourth aspect of the present invention, there is provided a manufacturing method of an epitaxial growth substrate, the manufacturing method including: performing an ingot annealing process on an ingot, the ingot annealing process in which a temperature is maintained between 1200° C. and 1400° C. for 5 hours to 20 hours; and slicing the ingot on which the ingot annealing process is performed.

### BRIEF DESCRIPTION OF THE DRAWINGS

The above and other objects, advantageous effects, and features of the present invention will be more fully understood from the detailed description given hereinbelow and the appended drawings which are given by way of illustration only, and thus are not intended as a definition of the limits of the present invention, wherein:

FIG. 1 is a graph showing the X-ray full width at half maximum (FWHM) of NGO substrates before and after a wafer annealing process;

FIG. 2 is a graph showing the surface roughness (Ra) of the NGO substrates after the wafer annealing process;

FIG. 3 shows an NGO substrate and a GaN thick film layer of a monocrystal thereon of a GaN substrate according to an embodiment of the present invention;

FIG. 4 shows a GaN self-supporting substrate according to the embodiment of the present invention; and

FIG. 5 shows an NGO substrate and a Gan thick film layer of a polycrystal thereon of a GaN substrate according to a comparative example of the present invention.

### DESCRIPTION OF THE PREFERRED EMBODIMENTS

[Development of the Present Invention]

In the following, the development of the present invention is described in detail.

In general, an NGO substrate which is used as a growth substrate for manufacturing a GaN-based semiconductor substrate is produced by slicing an NGO ingot grown by a crystal pulling method, such as a czochralski (CZ) method, into wafers. Before and after the slicing of the NGO ingot, an annealing process (ingot annealing process or wafer annealing process) is performed at a prescribed temperature.

The ingot annealing process is performed between growing an NGO crystal and polishing an NGO substrate, and includes annealing an NGO ingot and an NGO ingot block, which is produced by cutting or dividing an NGO ingot into a plurality of NGO ingot blocks.

Preferably, the thickness of an NGO ingot and an NGO ingot block is 40 mm or less, and more preferably 10 mm or less. When the thickness thereof is 60 mm or more, an effect from the annealing process may not reach into an NGO crystal. In such cases, a GaN polycrystal is often produced when a GaN thick film layer is grown by HVPE later.

An experiment was conducted with the following view: when the wafer annealing process is performed after the ingot annealing process and the slicing, the heat resistance property of the produced NGO substrate is changed depending on the temperature (ingot annealing temperature, hereinafter) and the duration of the ingot annealing process, and thereby influencing the growth of a GaN thick film layer, the wafer annealing process which acts as a temperature-rise process for the growth of the GaN thick film layer.

In order to examine whether the heat resistance property (heat stability) of an NGO substrate is different depending on the ingot annealing temperature, the ingot annealing process was performed on NGO ingots at different temperatures. That is, the ingot annealing process in which a temperature is maintained at 1200° C., 1300° C., 1400° C., or 1450° C. for 10 hours was performed on each NGO ingot. Thereafter, the wafer annealing process (the temperature-rise process for the growth of a GaN thick film layer) was performed on the NGO substrates produced by slicing each of the NGO ingots, the wafer annealing process in which a temperature is maintained at 1000° C. for 15 minutes.

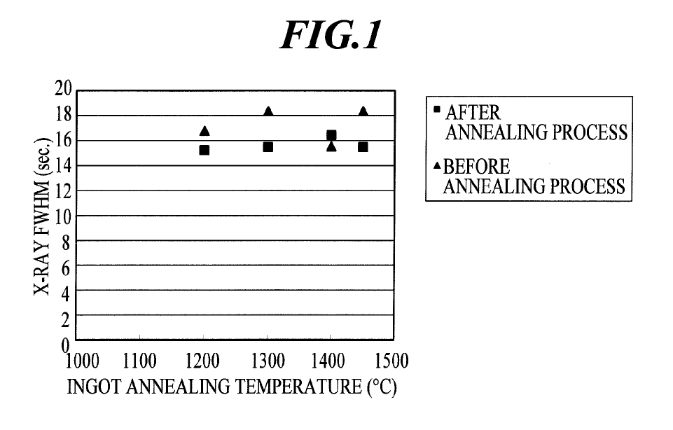

FIG. 1 is a graph showing the X-ray full width at half maximum (FWHM) of NGO substrates before and after the wafer annealing process.

As shown in FIG. 1, the X-ray FWHM of the NGO substrates on which the ingot annealing process was performed at a temperature of 1200° C. to 1450° C. was 15.55 seconds to 18.36 seconds before the wafer annealing process, and 15.22 seconds to 16.43 seconds after the wafer annealing process. That is, the X-ray FWHM of an NGO substrate changes very little between before and after the wafer annealing process. In other words, the result indicates that the crystallizability of an NGO substrate does not change depending on the ingot annealing temperature.

FIG. 2 is a graph showing the surface roughness (Ra) of the NGO substrates before and after the wafer annealing process.

As shown in FIG. 2, the surface roughness of the NGO substrates on which the ingot annealing process was performed at 1300° C. was 1.23 nm, and the surface roughness of the NGO substrates on which the ingot annealing process was performed at 1450° C. was more than 10 nm. Since the surface roughness of the NGO substrates before the wafer annealing process was 0.15 nm, the surface roughness of the NGO substrates on which the ingot annealing process was performed at 1300° C. increased by 1.08 nm. That is, the surface of the NGO substrates further roughened by the surface roughness of 1.08 nm as compared with the surface thereof before the wafer annealing process.

From the result, it is said that the heat resistance property of an NGO substrate is changed depending on the ingot annealing temperature, and that when the ingot annealing temperature is too high, the surface roughness of the NGO substrate considerably increases, namely, the surface of the NGO substrate considerably deteriorates, by the temperature-rise process for the growth of a GaN thick film layer.

When the ingot annealing temperature is lower than 1200° C. (1100° C., for example), the strain in an ingot crystal is not perfectly removed, and hence the curvature of a wafer, which is produced by slicing the ingot, becomes large. Consequently, a necessary margin of the wafer for polishing the wafer becomes around 1.5 to 2.0 times more (200 μm to 500 μm), and accordingly, the manufacturing cost of an NGO substrate increases. Therefore, it is preferable to perform the ingot annealing process at 1200° C. or higher.

As a result of the above-described experiment, a view is held, the view that the surface roughness of an NGO substrate before growing a GaN thick film layer can be easily controlled to be within the range from 0.2 nm to 10 nm by using an NGO substrate which keeps an excellent heat resistance property thereof in growing a GaN thick film layer, namely, an NGO substrate of which the surface roughness does not considerably increase, and accordingly, of which the surface does not considerably deteriorate, during the temperature-rise process by which a temperature increases until reaching a growth temperature of a GaN thick film layer. Accordingly, the present invention has been developed.

In the following, an embodiment of the present invention is described in detail.

In the embodiment, a manufacturing method of a GaN substrate is described, the manufacturing method by which GaN, which is a GaN-based semiconductor, is epitaxially grown on an NGO substrate composed of a perovskite-type rare-earth element by using HVPE so that a GaN substrate is manufactured.

By utilizing HVPE, a chloride gas (GaCl) and ammonia (NH₃) react with each other so that a GaN layer is epitaxially grown on the NGO substrate, the chloride gas which is generated from hydrochloric acid (HCl) and gallium (Ga) of Group III metal.

In the embodiment, as a growth substrate for a GaN thick film layer, an NGO substrate is used, the NGO substrate having the heat resistance property which dose not make the surface roughness thereof more than 10 nm during the temperature-rise process (including maintaining the reached temperature until the temperature becomes stable) by which a temperature increases until reaching a growth temperature (900° C. to 1050° C.). For example, an NGO substrate having such a heat resistance property is produced by performing the ingot annealing process on an NGO ingot grown by the CZ method, the ingot annealing process in which a temperature is maintained at between 1200° C. and 1400° C. for 5 hours to 20 hours. If the temperature during the ingot annealing process is lower than 1200° C., the removal of the residual strain in the grown crystal, which is the primary point for the present invention, becomes difficult. Hence, the lower limit of the temperature is set to 1200° C.

In general, the surface roughness of an NGO substrate used for growing GaN is originally around 0.10 nm to 0.17 nm. Conventionally, immediately before growing a GaN thick film layer, namely, after the temperature-rise process, the surface roughness of an NGO substrate is more than 10 nm. However, when an NGO substrate according to the embodiment of the present invention is used, the surface roughness of the NGO substrate after the temperature-rise process is 6.0 nm to 9.6 nm. That is, by using an NGO substrate according to the embodiment of the present invention, the surface roughness thereof can be easily controlled to be within the range from 0.2 nm to 10 nm.

According to the embodiment of the present invention, it can be prevented that the surface roughness of an NGO substrate considerably increases, namely, the surface thereof considerably deteriorates, which is caused by maintaining a high temperature during the temperature-rise process for the growth of a GaN thick film layer. Consequently, the productivity of a GaN-based semiconductor substrate can be remarkably increased.

### EMBODIMENT

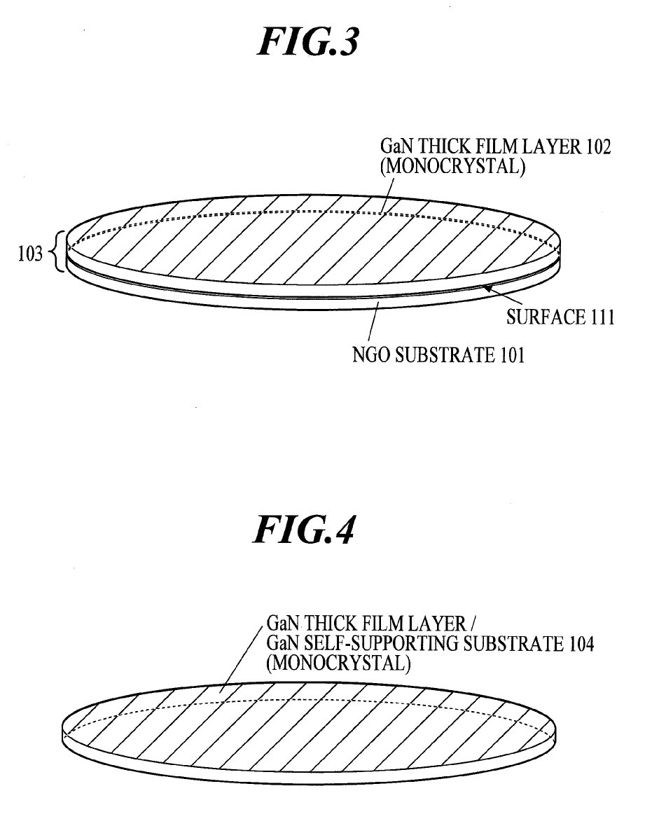

In an embodiment, an NGO substrate 101 having a surface 111, the NGO substrate 101 on which the ingot annealing process was performed in advance was deposited on a substrate holder, the ingot annealing process in which a temperature was maintained at 1300° C. for 10 hours. Then, the temperature-rise process was performed on the NGO substrate 101, the temperature-rise process in which a temperature was increased to 1000° C., and then maintained for 15 minutes so as to be stable. Next, a GaN thick film layer 102 having the thickness of 3000 μm was grown on the NGO substrate 101, or more specifically, on the surface 111 of the NGO substrate 101, by supplying a source gas. The source gas was composed of an NH₃ gas and GaCl generated from a Ga metal deposited in a device and an HCl gas . The source gas was supplied by using an N₂ gas as a carrier gas in such a way that the partial pressure of HCl was 1.06×10⁻² atm, and the partial pressure of NH₃ was 5.00×10⁻² atm. The obtained GaN thick film layer 102 was a monocrystal as shown in FIG. 3, and had the X-ray FWHM of 430 seconds and excellent crystallizability. Consequently, a GaN substrate 103 was obtained, and accordingly, a GaN self-supporting substrate 104 was obtained as shown in FIG. 4.

While the surface roughness of the NGO substrate 101 was originally 0.15 nm, the surface roughness thereof immediately before growing the GaN thick film layer 102 was 1.23 nm.

[Comparative Example]

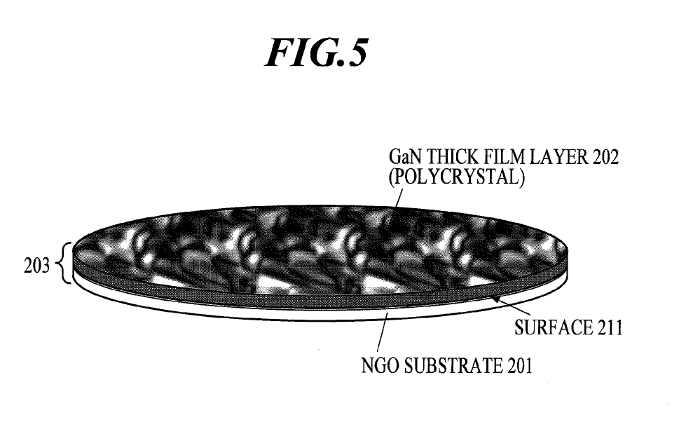

In a comparative example, an NGO substrate 201 having a surface 211, the NGO substrate 201 on which the ingot annealing process was performed in advance was deposited on a substrate holder, the ingot annealing process in which a temperature was maintained at 1450° C. for 10 hours. Then, the temperature-rise process was performed on the NGO substrate 201, the temperature-rise process in which a temperature was increased to 1000° C., and then maintained for 15 minutes so as to be stable. The surface roughness of the NGO substrate 201 after the temperature-rise process was 13 nm. Next, a GaN thick film layer 202 having the thickness of 3000 μm was grown on the NGO substrate 201, or more specifically, on the surface 211 of the NGO substrate 201, by supplying a source gas. The source gas was composed of an NH₃ gas and Gad generated from a Ga metal deposited in a device and an HCl gas . The source gas was supplied by using an N₂ gas as a carrier gas in such a way that the partial pressure of HCl was 1.06×10⁻² atm, and the partial pressure of NH₃ was 5.00×10⁻² atm. The obtained GaN thick film layer 202 was a polycrystal as shown in FIG. 5, and had the X-ray FWHM of 3240 seconds. Consequently, a GaN substrate 203 was obtained.

While the surface roughness of the NGO substrate 201 was originally 0.15 nm, the surface roughness thereof immediately before growing the GaN thick film layer 202 was 13 nm. That is, the surface roughness thereof exceeded 10 nm, and accordingly the surface of the NGO substrate 201 deteriorated.

As described above, by using an NGO substrate of which the surface roughness does not exceed 10 nm during the temperature-rise process by which a temperature increases until reaching the growth temperature of a GaN thick film layer, the surface roughness of the NGO substrate immediately before growing a GaN thick film layer can be easily controlled to be within the range from 0.2 nm to 10 nm. Consequently, the productivity of a GaN substrate can be remarkably increased.

In addition, since it is not required to grow a GaN low-temperature protection layer, it does not happen that the quality of a GaN low-temperature protection layer influences the quality of a GaN thick film layer. Consequently, a high-quality GaN substrate can be manufactured.

Furthermore, the performance of a semiconductor device can be improved by using a GaN self-supporting substrate to manufacture the semiconductor device, the GaN self-supporting substrate which is obtained by detaching the GaN thick film layer from the GaN substrate, slicing the detached GaN thick film layer, and then polishing the sliced GaN thick film layer.

In the above, the present invention is described in detail based on the embodiment. However, the present invention is not limited to the embodiment, and hence can be appropriately modified without departing from the scope of the present invention.

In the embodiment, a case is described, the case where GaN of a nitride-based compound semiconductor is grown on a growth substrate. However, the present invention can also be applied to a case where another nitride-based compound semiconductor (layer) is grown on a growth substrate. The nitride-based compound semiconductor is expressed by InₓGa_{y}Al_{1-x-y}N (0≦x+y≦1, 0≦x≦1, 0≦y≦1) . For example, the nitride-based compound semiconductor is GaN, InGaN, AlGaN, InGaAlN, or the like.

In the embodiment, a case is described, the case where HVPE is used. However, the present invention can also be applied to a case where the nitride-based compound semiconductor layer is epitaxially grown by utilizing metal organic chemical vapor deposition (MOCVD), molecular beam epitaxy (MBE), or the like.

Furthermore, it is possible that the present invention is applied to a case where another perovskite-type rare-earth substrate (NdAlO₃ or NdInO₃, for example) is used as a growth substrate instead of the NGO substrate.

According to a first aspect of the embodiment, there is provided an epitaxial growth substrate including: a surface not roughening over a surface roughness of 10 nm during a temperature-rise process by which a temperature increases until reaching a growth temperature of a nitride-based compound semiconductor layer, the growth temperature being 900° C. to 1050° C., wherein the nitride-based compound semiconductor layer is epitaxially grown directly on the epitaxial growth substrate at the growth temperature.

Preferably, the epitaxial growth substrate is made of NdGaO₃.

Preferably, the epitaxial growth substrate is subjected to an ingot annealing process in advance, the ingot annealing process in which a temperature is maintained between 1200° C. and 1400° C. for 5 hours to 20 hours.

According to a second aspect of the embodiment, there is provided a nitride-based compound semiconductor substrate including: the epitaxial growth substrate; and a nitride-based compound semiconductor layer disposed on the epitaxial growth substrate, wherein the nitride-based compound semiconductor layer is epitaxially grown directly on the epitaxial growth substrate.

According to a third aspect of the embodiment, there is provided a nitride-based compound semiconductor self-supporting substrate obtained by detaching the nitride-based compound semiconductor layer from the nitride-based compound semiconductor substrate, slicing the detached nitride-based compound semiconductor layer, and polishing the sliced nitride-based compound semiconductor layer.

According to a fourth aspect of the embodiment, there is provided a manufacturing method of an epitaxial growth substrate, the manufacturing method including: performing an ingot annealing process on an ingot, the ingot annealing process in which a temperature is maintained between 1200° C. and 1400° C. for 5 hours to 20 hours; and slicing the ingot on which the ingot annealing process is performed.

The above-described embodiment should be regarded as an instance, not as a limit, in every respect. The scope of the present invention should be limited solely by the claims that follow, not by the above-described embodiment. The proper scope of the present invention should be determined only by the broadest interpretation of the appended claims so as to encompass all modifications and equivalents insofar as they do not depart from the spirit and scope of the present invention.

The entire disclosure of Japanese Patent Application No. 2010-050013 filed on Mar. 8, 2010 including the description, claims, drawings, and abstract is incorporated herein by reference in its entirety.

What is claimed is:

1. An epitaxial growth substrate comprising:
a surface not roughening over a surface roughness of 10 nm during a temperature-rise process by which a temperature increases until reaching a growth temperature of a nitride-based compound semiconductor layer, the growth temperature being 900° C. to 1050° C., wherein the nitride-based compound semiconductor layer is epitaxially grown directly on the epitaxial growth substrate at the growth temperature.

2. The epitaxial growth substrate according to claim 1, wherein the epitaxial growth substrate is made of NdGaO₃.

3. The epitaxial growth substrate according to claim 2, wherein the epitaxial growth substrate is subjected to an ingot annealing process in advance, the ingot annealing process in which a temperature is maintained between 1200° C. and 1400° C. for 5 hours to 20 hours.

4. A nitride-based compound semiconductor substrate comprising:
the epitaxial growth substrate according to claim 1; and
a nitride-based compound semiconductor layer disposed on the epitaxial growth substrate, wherein
the nitride-based compound semiconductor layer is epitaxially grown directly on the epitaxial growth substrate.

5. A nitride-based compound semiconductor self-supporting substrate obtained by detaching the nitride-based compound semiconductor layer from the nitride-based compound semiconductor substrate according to claim 4, slicing the detached nitride-based compound semiconductor layer, and polishing the sliced nitride-based compound semiconductor layer.

6. A manufacturing method of an epitaxial growth substrate, the manufacturing method comprising:
performing an ingot annealing process on an ingot, the ingot annealing process in which a temperature is maintained between 1200° C. and 1400° C. for 5 hours to 20 hours; and
slicing the ingot on which the ingot annealing process is performed.
